(19) United States
(12) Patent Application Publication
(10) Pub. No.: US 2017/0200815 A1
(43) Pub. Date: Jul. 13, 2017

(54) CASIMIR-EFFECT DEVICE

(71) Applicant: Elwha LLC, Bellevue, WA (US)

(72) Inventors: Kenneth G. Caldeira, Redwood City, CA (US); Bran Ferren, Beverly Hills, CA (US); William Gates, Medina, WA (US); W. Daniel Hillis, Cambridge, MA (US); Roderick A. Hyde, Redmond, WA (US); Muriel Y. Ishikawa, Livermore, CA (US); Jordin T. Kare, San Jose, CA (US); John Latham, Boulder, CO (US); Nathan P. Myhrvold, Medina, WA (US); Clarence T. Tegreene, Mercer Island, WA (US); David B. Tuckerman, Lafayette, CA (US); Thomas Allan Weaver, San Mateo, CA (US); Charles Whitmer, North Bend, WA (US); Lowell L. Wood, JR., Bellevue, WA (US); Victoria Y.H. Wood, Livermore, CA (US)

(21) Appl. No.: 14/984,722

(22) Filed: Dec. 30, 2015

(51) Int. Cl. H01L 29/66; H03K 17/687; H01L 29/84

(52) U.S. Cl. CPC H01L 29/66977; H01L 29/84; H03K 17/687

(57) ABSTRACT

A method of controlling a Casimir-effect device includes applying a voltage to a field-effect gate of the Casimir-effect device. The Casimir-effect device includes a conducting material and a semiconductor. The conducting material and semiconductor are separated by a gap to form the field-effect gate over at least a portion of the semiconductor facing the gap. The method further includes altering, in response to the applied voltage, a density of free charge carriers in the portion of the semiconductor facing the gap to control a nanoscale Casimir force between the conducting material and the portion of the semiconductor facing the gap.

### BACKGROUND

The Casimir effect is a nonlinear attractive force between conducting plates that arises from a quantized vacuum field around the plates. Such a force can be induced by virtual photons that fill the vacuum field, and the induced force varies based on the separation between the conducting surfaces of the plates. Certain photon modes are forbidden from the area of the separation between the plates (i.e. photon modes of wavelengths that are too large to fit within the separation). Due to this phenomenon, the energy density is lower between the plates than it is outside the plates, and a pressure is formed that pushes the plates together.

### SUMMARY

One embodiment relates to a method of controlling a Casimir-effect device. The Casimir-effect device comprises a conducting layer and a semiconducting layer, where the conducting layer and semiconducting layer are separated by a gap. The method includes applying an electric field to at least a portion of the semiconducting layer of the Casimir-effect device, via a voltage applied to an electrode, which forms a field-effect gate over at least a portion of the semiconducting layer facing the gap. The method further includes varying, in response to the applied voltage, a charge density of a surface portion of the semiconducting layer facing the gap to control a nanoscale Casimir force between the conducting layer and the surface portion of the semiconducting layer facing the gap. In response to the applied voltage, the surface portion of the semiconducting layer may vary from essentially conducting to essentially non-conducting.

Another embodiment relates to a Casimir-effect device. The device comprises a conducting layer and a semiconducting layer, where the conducting layer and semiconducting layer are separated by a gap. An electric field can be applied to the semiconducting layer to vary a charge density of a surface portion of the semiconducting layer, such that the surface portion of the semiconducting layer may vary from essentially conducting to essentially non-conducting. In some embodiments, the device comprises a moveable element. The moveable element may comprise the conducting layer or the semiconducting layer. The device further comprises a second semiconducting layer, wherein the moveable element is separated by a gap from the second semiconducting layer, and wherein the moveable element is configured to move in response to a Casimir force formed between the moveable element and the second semiconducting layer.

Another embodiment relates to a method of manufacturing a Casimir-effect device. The method comprises providing a conducting material. The method further comprises providing a second element comprising a semiconductor wherein the conducting material is separated by a gap from the second element. The method further comprises providing at least one electrode configured to apply an electric field to the semiconductor to vary a charge density of a surface portion of the semiconductor, such that the surface portion of the semiconductor varies from essentially conducting to essentially non-conducting.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIG. 1 is a diagram of the Casimir-effect on two conducting plates.

FIG. 2 is a block diagram of a Casimir-effect device, according to one embodiment.

FIG. 3A is a block diagram of a Casimir-effect device, according to one embodiment.

FIG. 3B is a block diagram of a Casimir-effect device, according to one embodiment.

FIG. 3C is a diagram of a Casimir-effect device, according to one embodiment.

FIG. 4 is a flow diagram of a process for controlling a nanoscale Casimir force to move a moveable element, according to one embodiment.

FIG. 5 is a flow diagram of a process for providing a Casimir-effect device, according to one embodiment.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the scope of the subject matter presented here.

Referring generally to the figures, various embodiments of a Casimir-effect transistor devices are shown and described. The Casimir-effect is an attractive force that arises in a vacuum space, which is filled by virtual photons. In general, the modes of the virtual photons are uniform in density, and there is no Casimir-effect. However, if two conducting surfaces are introduced into the space and the conducting surfaces are arranged sufficiently close together (e.g., parallel) to form a cavity therebetween, photon modes of wavelengths that are larger than the cavity cannot exist within the cavity. As a result, the energy density (i.e., the virtual radiation from the virtual photons) is lower in the cavity than it is outside the conducting surfaces, which materializes as a pressure from the higher energy density outside the cavity that pushes the surfaces together.

Although the resulting Casimir force is present, it is typically negligible until the conducting surfaces are spaced sufficiently close together. The Casimir force is non-linear, and is inversely proportional to the fourth power of the separation between the conducting surfaces (the Casimir force varies according to L⁻⁴, where L equals the separation between the conducting surfaces). Thus, to obtain a measureable effect, the conducting surfaces generally need to be spaced at a separation on the nanometer scale (or smaller). An example physical scale at which the Casmir force is significant is for a conducting surface spacing of 10 nanometers. In the embodiments described herein, the Casimir-effect can be switched on and off (or modulated), for example, by altering the conductivity of one or more of the conducting surfaces. By controlling the conductivity, the Casimir force may be increased or reduced as desired.

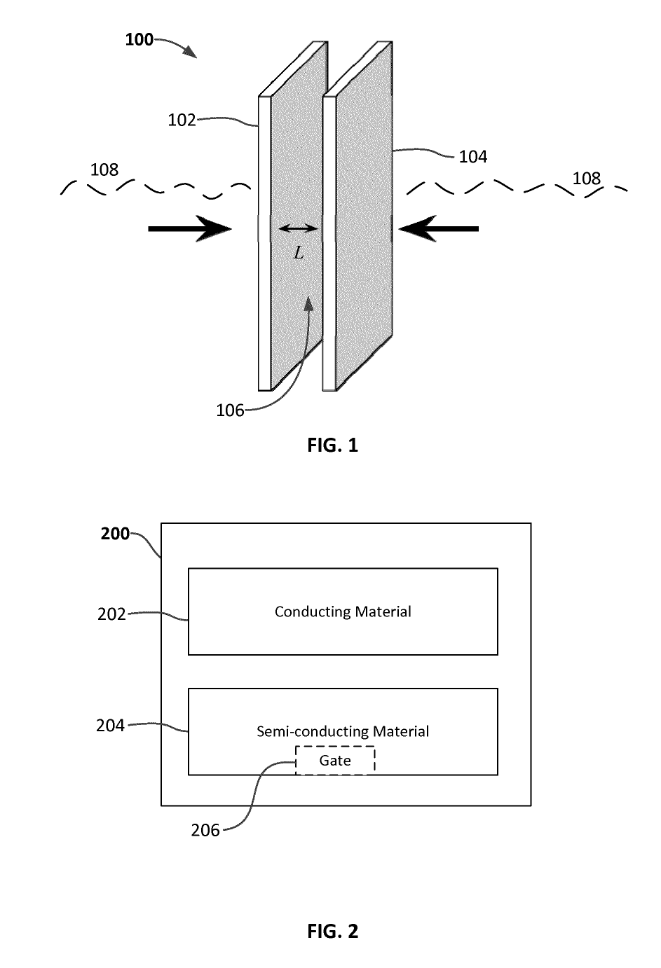

Referring to FIG. 1, a diagram 100 depicts the Casimir-effect on two conducting plates. Diagram 100 includes a first conducting plate 102 and a second conducting plate 104. Conducting plates 102 and 104 are shown as being separated by a distance of L to form cavity 106 therebetween, and conducting plates 102 and/or 104 may be formed on the surface of a substrate. In one embodiment, the distance L is at the nanometer scale (e.g., 1 nm or less, 5 nm or less, 10 nm or less, etc.). Conducting plates 102 and 104 may be enclosed by a vacuum field 108, which is filled with virtual photons. At the distance of L, certain modes of the virtual photons of field 108 (e.g., modes having a wavelength greater than greater than L) cannot fit within cavity 106. Because the certain modes cannot fit within cavity 106, the energy density within cavity 106 is less than the energy density in field 108, and a force is exerted on the outside of plates 102 and 104 that is greater than the force exerted on the inside of plates 102 and 104, which pushes plates 102 and 104 together. By altering the conductivity of plates 102 and/or 104, the strength of the Casimir-effect can be controlled, and/or turned off entirety (e.g., if plate 102 and/or 104 is altered such that either becomes an insulator). For example, in one embodiment, plate 102 or 104 may be a conducting surface (e.g., conducting material, conducting layer) comprised of N-type doped silicon, which normally has a high density off free charge carriers (electrons) but is adjacent to (but electrically isolated from) a gate structure, such that applying a negative voltage to the gate can push the electrons out of the conducting layer, and thereby transform the plate into an insulator. Alternatively, plate 102 (or 104) can be doped such that it is normally an insulator, but has a gate that can be positively charged to attract electrons and thereby transform the plate into a conductor. The scope of the present disclosure is not limited to a specific manner of adjusting the insulating properties of plates 102 and 104.

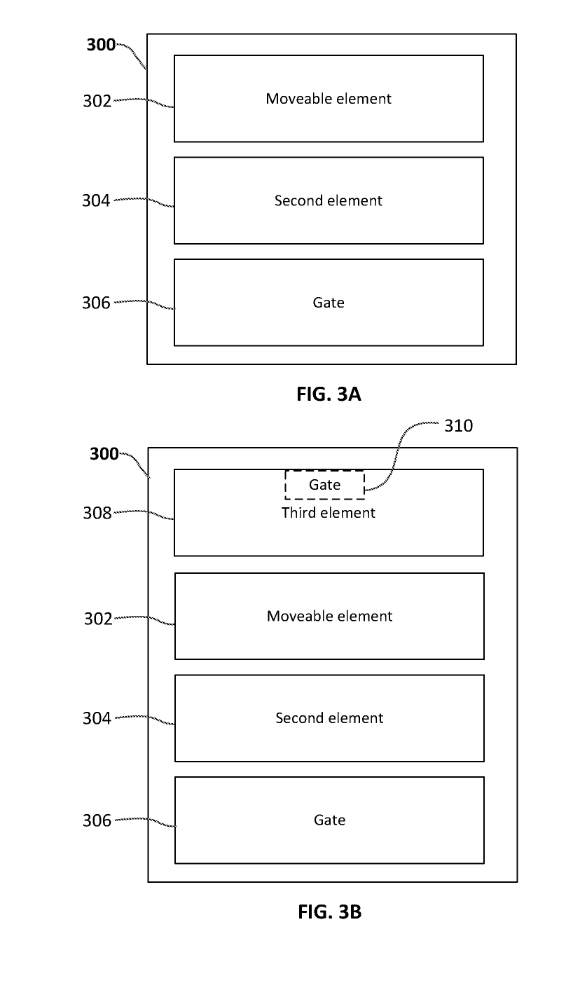

Referring to FIG. 2, a block diagram of Casimir-effect device 200 is shown, according to one embodiment. Casimir-effect device 200 includes at least one conducting material 202 and a semiconducting material 204 (i.e., a semiconductor device, semiconducting layer). In one embodiment, conducting material 202 is a nominally flat surface and semiconducting material 204 has a surface that is arranged parallel to conducting material 202. The conducting material 202 may also be referred to as a conducting layer herein. Conducting material 202 and semiconducting material 204 are separated by a small gap (e.g., a nanometer-scale gap, or smaller). For example, in one embodiment, the gap is 1 nanometer. In another embodiment, the gap is 10 nanometers, etc. In an embodiment, an electric field is applied to the semiconductor material to vary a charge density near the surface or a surface portion of the semiconductor material that is facing the gap. The electric field may vary a charge density of the surface portion of the semiconductor material facing the gap. In an embodiment, the near surface of the semiconductor material may vary from essentially conducting to essentially non-conducting in response to the electric field. In some embodiments, the electric field is applied by applying a voltage between the conducting material 202 and the semiconducting material 204.

In some embodiments, a field-effect gate 206 is formed over at least a portion of semiconducting material 204, which may be used to control a Casimir force between conducting material 202 and semiconducting material 204. For example, a voltage can be applied to the field-effect gate 206 to alter the density of free charge carriers in a portion of semiconducting material 204 facing the gap. The field-effect gate 206 may be formed in various ways. In one embodiment, the field-effect gate 206 is formed by the conducting material 202 itself, which is insulated from semiconducting material 204 by the gap. In another embodiment, the field effect gate 206 is formed by a differently-doped region in contact with the semiconducting material 204. For example, the field effect gate 206 may include a portion of the semiconductor material 204. The field effect gate 206 may comprise the rear surface portion of the semiconducting layer having a different doping from the remainder of the semiconductor layer, and isolated from the remainder of the semiconductor layer by a P-N junction or a P-I-N junction. In another embodiment, the field-effect gate 206 is formed by an electrode that is insulated from semiconducting material 204 (e.g., semiconducting material 204 may comprise the channel of a metal-oxide-semiconductor-field-effect transistor (MOSFET)). Other known methods of forming field-effect gate 206 may also be utilized to alter the density of free charge carriers in the portion of semiconducting material 204 facing the gap.

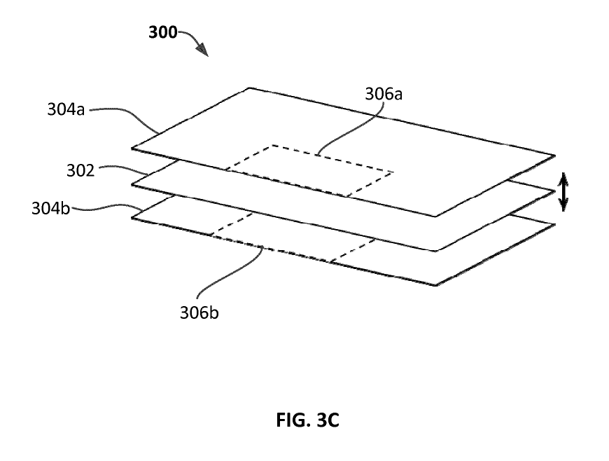

Referring to FIG. 3A, a block diagram of Casimir-effect device 300 is shown, according to one embodiment. Casimir-effect device 300 includes at least one moveable element 302 and at least one second element 304. Second element 304 may include one or more layers of material. In an embodiment where second element 304 includes a single layer, moveable element 302 may be on either side of the layer and configured to be attracted to the layer in response to a Casimir force. In one embodiment, moveable element 302 comprises conducting material and second element 304 comprises semiconducting material. In another embodiment, moveable element 302 comprises semiconducting material and second element 304 comprises conducting material. In general, moveable element 302 is separated by a gap from the second element 304, and moveable element 302 is configured to move in response to changes in the Casimir force formed between moveable element 302 and second element 304. Through the application or removal of a voltage to field-effect gate 306, the conductivity of the semiconductor material may be controlled and used to vary the Casimir force between moveable element 302 and second element 304. For example, with an increase in conductivity, the Casimir force may be turned on or increased, and with a decrease in conductivity, the Casimir force may be turned off or decreased. In response to the varied Casimir force, the position of moveable element 302 may change.

In one embodiment, second element 304 includes a surface that is nominally flat and moveable element 302 includes a conducting area that is parallel to the surface of second element 304. Moveable element 302 may be a conducting area on the surface of a disk or plate, and may move in a perpendicular manner with respect to an area of second element 304. Moveable element 302 may also include a mechanically moving element (e.g., an arm, a supporting element, etc.), or moveable element 302 may be part of a flexible material (e.g., a portion of a flexible conducting sheet, etc.). In another embodiment, moveable element 302 is a portion of a comparatively large sheet that is either contiguous or partially separated (e.g., a disk surrounded by an etched gap with supporting elements, etc.). In one embodiment, moveable element 302 has an area of 0.01 μm² or less. Moveable element 302 may be held away from second element 304 (i.e., opposing a Casimir force) by another non-Casimir force. In one embodiment, a spring force of the material comprising moveable element 302 may also be used to push moveable element 302 and second element 304 apart. In another embodiment, an electromagnetic force may also be induced to push moveable element 302 and second element 304 apart. In another embodiment, the mechanical elastic strain forces of the material of moveable element 302 (or of supporting elements) may be used to maintain a position of moveable element 302.

The interaction of a non-Casimir force and the Casimir force may be taken advantage of such that moveable element 302 may be positioned in at least two stable states (i.e. positions). This interaction of forces may be controlled by the voltage applied to the gate as described above. When applying the voltage to field-effect gate 306, the Casimir force may be controlled by dynamically adjusting Casimir properties of second element 304 or moveable element 302. This may include changing the conductive or insulating properties of second element 304 or moveable element 302. For example, the Casimir force may be switched on or off by altering the conductivity of the semiconductor (e.g., by applying or removing a voltage to field-effect gate 306 such that the semiconductor switches from being non-conductive to conductive, depending on the particular configuration of the gate and semiconductor). When the Casimir force is active and when moveable element 302 and second element 304 are sufficiently close together, the Casimir force can dominate over a non-Casimir force, and moveable element 302 and second element 304 can be pushed together into a first stable position. However, when the Casimir force is inactive, then the non-Casmir force can dominate, and moveable element 302 and second element 304 can be pushed or pulled apart into a second stable position.

Thus, in an embodiment having two stable states, the positioning of moveable element 302 and whether it is in the first or second stable position may be used to implement various transistor devices that control moveable element 302 by varying the Casimir force between moveable element 302 and second element 304. In one embodiment, Casimir-effect device 300 is a switch, and the movement of moveable element 302 acts to open or close an electrical contact of Casimir-effect device 300. In one stable position of moveable element 302, electricity may be allowed to flow through the closed contact. In another stable position of moveable element 302, the contact may be open, such that electricity may not flow therethrough. In another embodiment, Casimir-effect device 300 is an actuator, and the movement of moveable element 302 may perform the mechanical function of the actuator. For example, moveable element 302 may move a component of a microelectromechanical (MEMS) device.

In some embodiments, the interaction of the non-Casimir force and the highly nonlinear Casimir force may allow the device to be stable in either of two states even with a single value of the applied gate voltage. For example, with the Casimir effect active, the position of Casimir-effect device 300 may be stable in a first state with a relatively large first separation between and hold moveable element 302 and second element 304, where the Casimir force on element 302 is small, and may also be stable in a second state with relatively small second separation where the Casimir force on element 302 is large. However, if Casimir-effect device 300 is in the second state, it may be “reset” to the first state, with moveable element 302 in the first position, by deactivating or dynamically adjusting the Casimir force (e.g., by adjusting the conductivity of the semiconductor as described above).

Additional forces may also be utilized to change the position of moveable element 302. In one embodiment, electromagnetic or electrostatic attraction (directed towards or away from second element 304) is utilized. In another embodiment, repulsion from a third surface is utilized. In another embodiment, photon pressure may be utilized to move moveable element 302. In another embodiment, mechanical pressure (e.g., from an atomic force microscopy (AFM) tip or a microelectromechanical (MEMS) actuator, etc.) may be utilized. A bulk force or change in a property may be used to cause a bulk change in the position of multiple moveable elements (e.g., a temperature change). In another embodiment, a non-Casimir force that is holding moveable element 304 may be reduced (e.g., via the application of heat, etc.) so that the Casimir force, when activated, dominates over the non-Casimir force.

In some embodiments, the Casimir force may be used to both “pull in” (move from the first state with relatively greater separation to the second state with relatively lesser separation) a bi-stable device, and to hold the device in the second state. This may be done by using the gate to turn the Casimir effect fully on until moveable element 302 moves towards second element 304 (thereby increasing the Casimir force) and then reducing, but not completely eliminating, the Casimir effect. This may involve either setting the gate voltage to an intermediate value between the voltages associated with two areas of, e.g., element 304, with both areas being turned on (high Casimir force) to “pull in” moveable element 302 and only one being turned on to hold element 302 in the closer position. In the former case, the device may be reset to the first state by setting the gate voltage to the value for minimum Casimir effect; in the latter case, the device may be reset by setting both gates to turn off the Casimir effect.

Referring to FIG. 3B, a block diagram of Casimir-effect device 300 is shown, according to one embodiment. The Casimir-effect device 300 includes a third element 308 (e.g., counter layer) positioned on the opposite side of the moveable element 302 from the second element 304. The third element 308 may be configured and operate similarly to second element 304. In some embodiments, the third element 308 is placed at a larger distance from moveable element 302 than the second element. In other embodiments, the third element 308 may comprise low-conductivity or non-conducting material. The third element 308 may include a dummy gate 310. In an embodiment, the third element 308 serves to balance electrostatic forces on moveable element 302. The third element 308 may be referred to as a counter layer and be positioned adjacent to the moveable element. The third element 308 or counter layer may cancel out an electrostatic force or an electromagnetic force on the moveable element.

Referring to FIG. 3C, an embodiment of Casimir-effect device 300 is shown where second element 304 includes multiple layers 304a and 304b, moveable element 302 is positioned between layers 304a and 304b. In this manner, Casimir-effect device 300 can be configured as a bi-stable device, such that moveable element 302 can be move back and forth between the layers in response to Casimir forces. Moveable element 302 may comprise conducting material, and each layer 304a and 304b may comprise semiconducting material and include a field-effect gate 306a and 306b as described above, where each field-effect gate 306a and 306b is independently controllable. In this embodiment, moveable element 302 may be pulled from one side to the other by independently controlling Casimir forces from each layer (i.e., by altering the voltages applied to field-effect gate 306a and 306b). As discussed above, the position of moveable element 302 may be used to stored data (as a memory), open or close an electrical circuit (as a switch/relay), and perform a mechanical function (as an actuator, etc.). In one embodiment, Casimir-effect device 300 may be turned “on” or “off” depending on the position of moveable element 302, and whether it is closer to or contacting (either directly or via an intermediate connection) layer 304a or 304b.

In certain embodiments discussed herein, moveable element 302 may be configured to only rest in the first or second stable positions. However, it should be understood that the scope of the present disclosure is not limited to embodiments where moveable element 302 that is only capable of being set in two stable positions. For example, in one embodiment, moveable element 302 may be positioned in one or more stable intermediate positions in addition to the two stable positions discussed above.

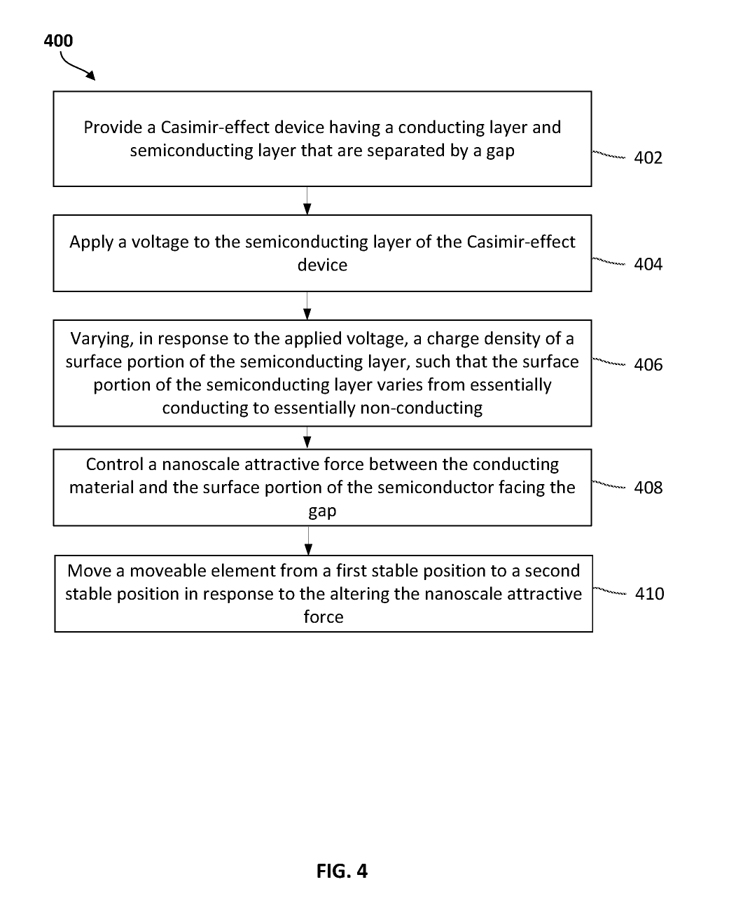

Referring to FIG. 4, a flow diagram of a process 400 for controlling a nanoscale Casimir force is shown, according to one embodiment. In alternative embodiments, fewer, additional, and/or different actions may be performed. Also, the use of a flow diagram is not meant to be limiting with respect to the order of actions performed. A Casimir-effect device is provided having a conducting layer and a semiconducting layer that are separated by a gap (402). A voltage is applied to the semiconducting layer of the Casimir-effect device (404). A charge density of a surface portion of the semiconducting layer is varied in response to the applied voltage. The surface portion of the semiconducting layer can vary from essentially conducting to essentially non-conducting (406). In some embodiments, in response to the applied voltage, the density of free charge carriers in the surface portion or any portion of the semiconductor facing the gap is altered. For example, the surface portion of the semiconducting layer can vary from conducting to non-conducting in response to the applied voltage. Due to the altered density of free charge carriers, the conductivity of the semiconducting layer is altered, and the nanoscale Casimir force between the conducting material and the portion of the semiconducting layer facing the gap is controlled (408). For example, changing the semiconductor from an insulator to a conductor (e.g., via increasing or decreasing applied voltage) results in an increased Casmir force, and changing the semiconductor from a conductor to an insulator (e.g., via increasing or decreasing the applied voltage) results in a decreased Casmir force. Whether an increase or decrease the applied voltage is required to alter the conductivity of the semiconductor (and control the Casimir force) can depend on the particular type of field-effect gate and semiconductor being used. In some embodiments, a moveable element can be moved from a first stable position to a second stable position in response to the altering the nanoscale attractive force (410).

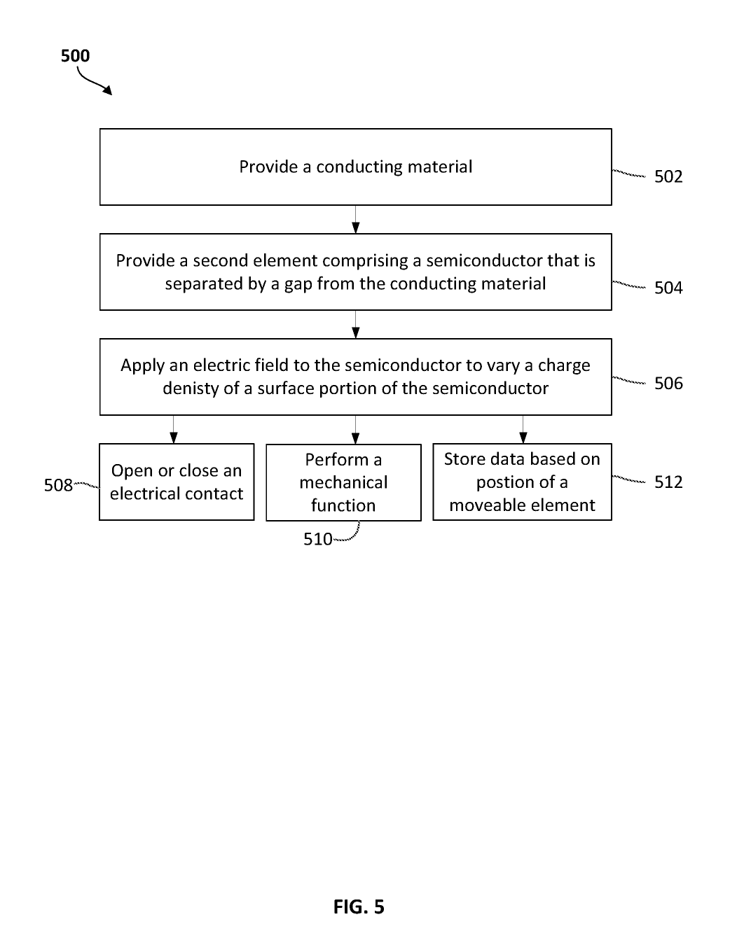

Referring to FIG. 5, a flow diagram of a process 500 for manufacturing a Casimir-effect device is shown, according to one embodiment. In alternative embodiments, fewer, additional, and/or different actions may be performed. Also, the use of a flow diagram is not meant to be limiting with respect to the order of actions performed. A conducting material is provided (502). A second element that comprises a semiconductor is provided and arranges such that it is separated by a gap from the conducting material. In some embodiments, a moveable element can be moved in response to a Casimir force formed between the conducting material and the second element. The moveable element may include the conducting material or the semiconductor. An electric field is applied to the semiconductor to vary a charge density of a surface portion of the semiconductor (506). The Casimir force may be controlled as discussed herein. In one embodiment, the Casimir force is controlled in response to a voltage that is applied to a gate of the semiconductor. The movement of the moveable element may also be configured for various purposes. For example, an electrical contact may be provided in the Casimir-effect device, and the movement may open or close an electrical contact of the Casimir-effect device (508). As another example, a mechanical element may be provided in the Casimir-effect device, and the movement of the moveable element may perform a mechanical function of the Casimir-effect device (510) (e.g., actuating the mechanical element, etc.). As another example, the movement of the moveable element may also store data (512) that is based on or represented by a position of the moveable element.

The construction and arrangement of the systems and methods as shown in the various embodiments are illustrative only. Although only a few embodiments have been described in detail in this disclosure, many modifications are possible (e.g., variations in sizes, dimensions, structures, shapes and proportions of the various elements, values of parameters, mounting arrangements, use of materials, colors, orientations, etc.). For example, the position of elements may be reversed or otherwise varied and the nature or number of discrete elements or positions may be altered or varied. Accordingly, all such modifications are intended to be included within the scope of the present disclosure. The order or sequence of any process or method steps may be varied or re-sequenced according to alternative embodiments. Other substitutions, modifications, changes, and omissions may be made in the design, operating conditions and arrangement of the embodiments without departing from the scope of the present disclosure.

The present disclosure contemplates methods, systems and program products on any machine-readable media for accomplishing various operations. The embodiments of the present disclosure may be implemented or modeled using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

Although the figures may show a specific order of method steps, the order of the steps may differ from what is depicted. Also two or more steps may be performed concurrently or with partial concurrence. All such variations are within the scope of the disclosure. Likewise, software implementations could be accomplished with standard programming techniques with rule-based logic and other logic to accomplish the various connection steps, processing steps, comparison steps and decision steps.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims.

1. A method of controlling a Casimir-effect device, comprising:
providing a Casimir-effect device comprising a conducting layer and a semiconducting layer, the conducting layer and the semiconducting layer separated by a small gap; and
applying an electric field to the semiconducting layer to vary a charge density of a surface portion of the semiconducting layer, such that the surface portion of the semiconducting layer varies from essentially conducting to essentially non-conducting.

2. The method of claim 1, wherein the conducting layer is insulated from the semiconducting layer by the gap.

3. The method of claim 1, wherein the electric field is provided by applying a voltage between the conducting layer and the semiconducting layer.

4. The method of claim 1, wherein the electric field is provided by a field effect gate positioned adjacent to the semiconducting layer.

5-8. (canceled)

9. The method of claim 1, wherein the conducting layer is a moveable layer or the semiconducting layer is a moveable layer.

10. (canceled)

11. The method of claim 9, wherein altering the nanoscale attractive force to the second value includes setting the nanoscale attractive force to a value configured to hold the moveable layer in the second stable position.

12. (canceled)

13. The method of claim 9, further comprising moving the moveable layer to the second stable position by setting the nanoscale attractive force to an intermediate value between the first value and the second value.

14. (canceled)

15. The method of claim 9, wherein altering the nanoscale attractive force includes setting a pair of attractive forces to a combined value configured to position the moveable layer in the second stable position, and deactivating one of the pair of attractive forces.

16-20. (canceled)

21. A Casimir-effect system, comprising:
a conducting layer; and
a semiconducting layer, the conducting layer and the semiconducting layer separated by a small gap;
wherein an electric field is applied to the semiconducting layer to vary a charge density of a surface portion of the semiconducting layer, such that the surface portion of the semiconducting layer varies from essentially conducting to essentially non-conducting.

22. The system of claim 21, wherein the conducting layer is insulated from the semiconducting layer by the gap.

23. The system of claim 21, wherein the electric field is provided by applying a voltage between the conducting layer and the semiconducting layer.

24. The system of claim 21, wherein a Casimir force is formed by varying a density of free charge carriers in a portion of the semiconducting layer.

25. The system of claim 21, further comprising a field effect gate positioned adjacent to the semiconducting layer, wherein the field effect gate provides the electric field.

26-29. (canceled)

30. The system of claim 21, wherein the conducting layer is a moveable layer or the semiconducting layer is a moveable layer.

31. The system of claim 30, wherein the moveable layer is configured to move from a first stable position to a second stable position in response to the altering a nanoscale attractive force between the conducting layer and the semiconducting layer from a first value to a second value, wherein the second value is greater than the first value.

32-46. (canceled).

47. The system of claim 31, wherein the moveable element is further configured to:
move to the second stable position in response to an increase in the Casimir force over a baseline amount; and
move to the first stable position in response to a decrease in the Casimir force below the baseline amount.

48. The system of claim 31, further comprising a second semiconducting layer, wherein the gap forms a second field-effect gate over a surface portion of the second semiconducting layer facing the gap, and wherein a Casimir force is formed based on varying a second density of free charge carriers in the surface portion of the second semiconducting layer.

49-51. (canceled)

52. The system of claim 48, wherein the system includes a second electrode insulated from the second semiconducting layer, and wherein the second field-effect gate is formed by the second electrode.

53. (canceled)

54. The system of claim 48, wherein the first semiconducting layer and second semiconducting layer are independently controllable.

55. The system of claim 21, further comprising a counter layer positioned adjacent to the moveable element, wherein the counter layer cancels out an electrostatic force or an electromagnetic force on the moveable element.

56. The system of claim 21, further comprising a supporting element that provides a mechanical restoring force on the moveable element to maintain a position of the moveable element.

57. A method of manufacturing a Casimir-effect device, comprising:
providing a conducting layer comprising a conducting material;
providing a second element comprising a semiconducting layer comprising a semiconductor, wherein the conducting material is separated by a gap from the second element, and
applying an electric field to the semiconductor to vary a charge density of a surface portion of the semiconductor, such that the surface portion of the semiconductor varies from essentially conducting to essentially non-conducting.

58. The method of claim 57, wherein the conducting layer is insulated from the semiconducting layer by the gap.

59. The method of claim 57, wherein the electric field is provided by applying a voltage between the conducting layer and the semiconducting layer.

60. The method of claim 57, wherein a Casimir force is formed by varying a density of free charge carriers in the surface portion of the semiconducting layer.

61. The method of claim 57, further comprising a field effect gate positioned adjacent to the semiconducting layer, wherein the field effect gate provides the electric field.

62-65. (canceled)

66. The method of claim 57, wherein the conducting layer is a moveable layer or the semiconducting layer is a moveable layer.

67. The method of claim 66, wherein the moveable layer is configured to move from a first stable position to a second stable position in response to the altering a nanoscale attractive force between the conducting layer and the semiconducting layer.

68-71. (canceled)

72. The method of claim 67, wherein altering the nanoscale attractive force includes setting a pair of attractive forces to a combined value configured to position the moveable layer in the second stable position, and deactivating one of the pair of attractive forces.

73-76. (canceled)

77. The method of claim 67, wherein the mechanical function comprises moving a MEMS device.

78. The method of claim 67, wherein the moveable element is further configured to reset to the first stable position in response to an applied independent mechanism.

79-82. (canceled)

83. The method of claim 67, wherein the moveable element is further configured to:
move to the second stable position in response to an increase in the Casimir force over a baseline amount; and
move to the first stable position in response to a decrease in the Casimir force below the baseline amount.

84. The method of claim 67, further comprising a second semiconducting layer, wherein the gap forms a second field-effect gate over a surface portion of the second semiconducting layer facing the gap, and wherein a Casimir force is formed based on varying a second density of free charge carriers in the surface portion of the second semiconducting layer.

85-90. (canceled)

91. The method of claim 57, further comprising a counter layer positioned adjacent to the moveable element, wherein the counter layer cancels out an electrostatic force or an electromagnetic force on the moveable element.

92. The method of claim 57, further comprising a supporting element that provides a mechanical restoring force on the moveable element to maintain a position of the moveable element.
